(19) United States
(12) Patent Application Publication
(10) Pub. No.: US 2009/0196006 A1
(43) Pub. Date: Aug. 6, 2009

(54) Substrate structure of secure digital input/output module interface and its manufacturing method

(76) Inventor: Yi-Chen Chen, Longtan Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/068,138

(22) Filed: Feb. 4, 2008

(51) Int. Cl. H05K 7/18; H05K 7/00; H01L 21/60

(52) U.S. Cl. 361/813; 438/111; 257/E21.506

(57) ABSTRACT

A substrate structure of a secure digital input/output module interface and its manufacturing method are disclosed herein. First, a substrate is provided, wherein the substrate has a plurality of conductive contact portions abreast arranged on a lower surface of the substrate. Next, a lead frame with a side rail and a plurality of fingers abrest arranged thereon is provided, wherein any one of those fingers has an internal contact and an external contact. Then, those internal contacts of those fingers are electrically connected to those conductive contact portions of the substrate. Further, a sigulation process and a molding process are provided to form a single structure of secure digital interface module. Those fingers of the lead frame are positioned one-on-one to those conductive contact portions of the substrate to improve the mechanical properties and reduce the size of the substrate.

### BACKGROUND OF THE INVENTION

1. Field of the Invention

The present invention relates to an improvement in a substrate structure of a secure digital input/output module interface and its manufacturing method.

2. Description of the Prior Art

A secure Digital Input/Output (SDIO) is utilized to convert relative application module signals by using the golden fingers of SDIO interface card so as to access or write data into the host. In other words, a user can utilize a SD expansion slot to expand other peripheral hardware. Currently, most electronic equipments are provided with the SD expansion slot. The SD expansion slot not only can compatible with SD memory card but also support the I/O equipment of SD interface, and it may be configured with an application module, such as Bluetooth card, Wireless Fidelity card (Wi-Fi card), global positioning system (GPS), digital camera card (DC), frequency modulation broadcasting card, fingerprint recognition system and so on.

Please refer to the FIG. 1A, FIG. 1B, FIG. 1C and FIG. 1D, FIG. 1A, FIG. 1B, FIG. 1C and FIG. 1D are respectively cross-sectional diagrams illustrating the conventional process procedure of SDIO card. As shown in FIG. 1A, the process procedure of SDIO card mainly includes following steps. Firstly, a substrate 10 having a plurality of golden fingers 12 is provided. Next, a tin soldering paste 20 is printed on the surface of the substrate 10 by using the surface mounting technology (SMT). Thereafter, an application module 30 is mounted on the substrate 10 and then reflow process is executed. Subsequently, a probe (not shown) is utilized to test the electricity toward direction A. Finally, the assembling procedure is processed. A housing 40 is utilized to cover the foregoing elements and then the structure can be shaped by using ultrasonic fixation method. Finally, FIG. 1D shows the final structure, which includes the housing 40 and the substrate 10. The application module 30 is set at a top surface of the substrate 10. In the meanwhile, a plurality of golden fingers 12 of the SDIO interface are formed on a corresponding lower surface of the substrate 10.

Owing to the plugging in/out issue of the SDIO card the golden fingers should be performed to meet some mechanical properties such as card insertion force, card withdrawal force, durability cycles and so on. As a consequence, a thick-hard gold needs to be coated on those golden fingers so that the production expense cannot be saved. Additionally, as a result of the substrate 10 only carried the application module 30, there must be a lot of unused space thereabout. Therefore, the utility rate of the substrate 10 is not well.

### SUMMARY OF THE INVENTION

The advantages of the present invention will become apparent from the following description taken in conjunction with the accompanying drawings wherein are set forth, by way of illustration and example, certain embodiments of the present invention.

One object of the present invention is to provide a substrate structure of a secure digital input/output module interface and its manufacturing method, which utilizes a lead frame provided with a plurality of external contacts of a SDIO module interface instead of the conventional golden fingers on the substrate. Therefore, the mechanical properties, such as card insertion/withdraw enforce, can be elevated.

One object of the present invention is to provide a substrate structure of a secure digital input/output module interface and its manufacturing method, which utilizes a lead frame instead of conventional golden fingers of the substrate to reduce the substrate area and decrease the production cost.

To achieve the abovementioned objective, the present invention proposes a substrate structure of a secure digital input/output module interface including: a substrate having a plurality of conductive contact portions abreast arranged on a lower surface of the substrate, and a lead frame having a side rail and a plurality of fingers abreast arranged on the side rail, wherein any one of those fingers includes an internal contact and an external contact; the internal contact of any one of those fingers electrically contacts to any one of those conductive contact portions of the substrate; and the external contact of any one of those fingers is jointed to the side rail.

To achieve the abovementioned objective, the present invention proposes a substrate structure of secure digital input/output module interface including: a substrate having a plurality of conductive contact portions abreast arranged on a lower surface of the substrate; and a plurality of fingers relatively positioned to the conductive contact portions, wherein any one of those fingers includes an internal contact and an external contact; the internal contact of any one of those fingers electrically contacts to any one of those conductive contact portions of the substrate; and the external contact of any one of those fingers is formed to be a free end.

To achieve the abovementioned objective, the present invention proposes a manufacturing method to a substrate of secure digital input/output module interface including: providing a substrate with a plurality of conductive contact portions abreast arranged on a lower surface of the substrate; providing a lead frame with a side rail and a plurality of fingers abreast arranged on the side rail, wherein any one of those fingers includes an internal contact and an external contact; and electrically connecting those internal contacts of those fingers to any one of those conductive contact portions of the substrate.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1A, FIG. 1B, FIG. 1C and FIG. 1D are respectively cross-sectional diagrams illustrating the conventional process procedure of the SDIO card;

FIG. 2A, FIG. 2B and FIG. 2C are respectively top-view diagrams illustrating a substrate of a secure digital input/output module interface manufacturing method according to one embodiment of the present invention;

FIG. 2D-1 and FIG. 2D-2 are respectively a top-view diagram and a bottom-view diagram illustrating the substrate structure of the secure digital input/output module interface according to one embodiment of the present invention;

FIG. 2D-3 is a cross-sectional diagram that takes from the cross-segment BB of FIG. 2D-2;

FIG. 3A is a cross-sectional diagram illustrating a structure of the secure digital input/output module interface;

FIG. 3B-1 is a 3-dimensional diagram illustrating a structure of the secure digital input/output module interface; and

FIG. 3B-2 is a partially enlarged diagram according to FIG. 3B-1.

### DESCRIPTION OF THE PREFERRED EMBODIMENT

The detailed explanation of the present invention is described as following. The described preferred embodiments are presented for purposes of illustrations and description, and they are not intended to limit the scope of the present invention.

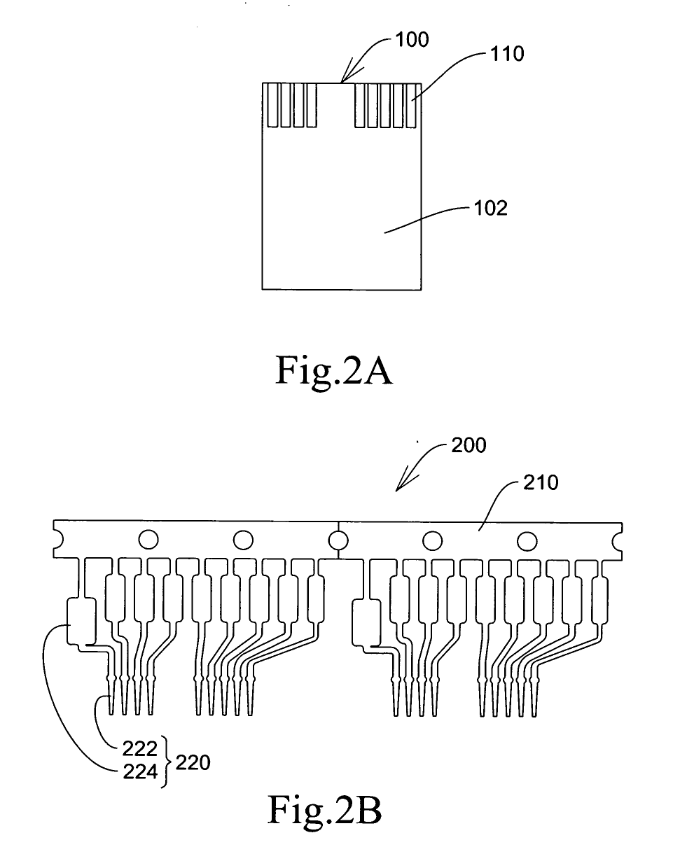

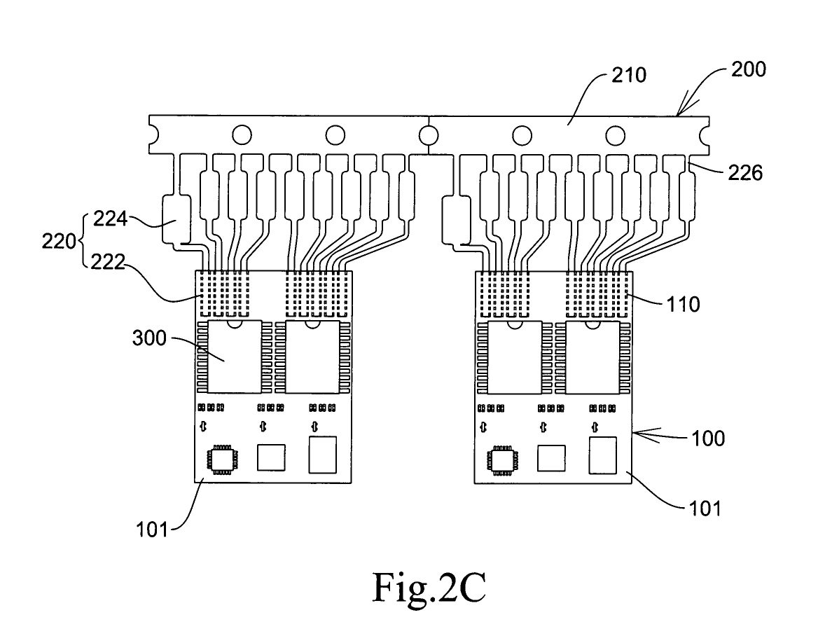

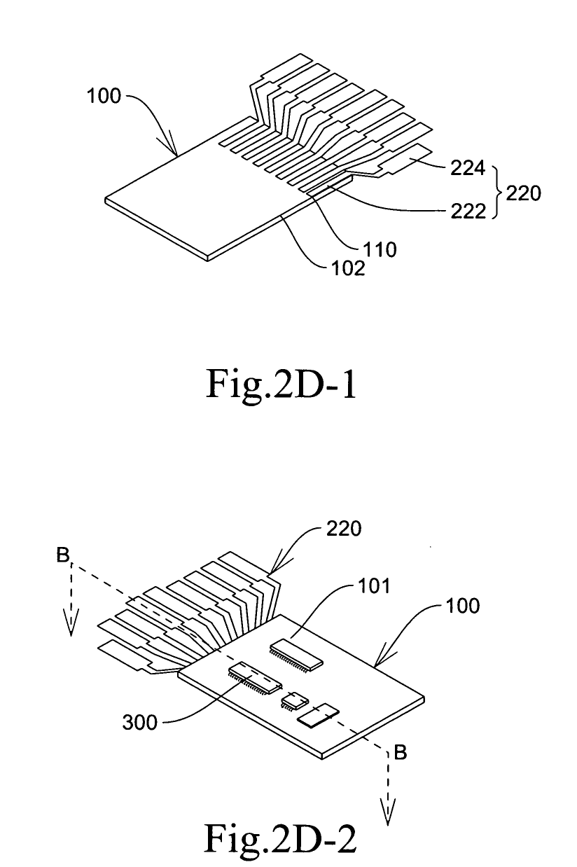

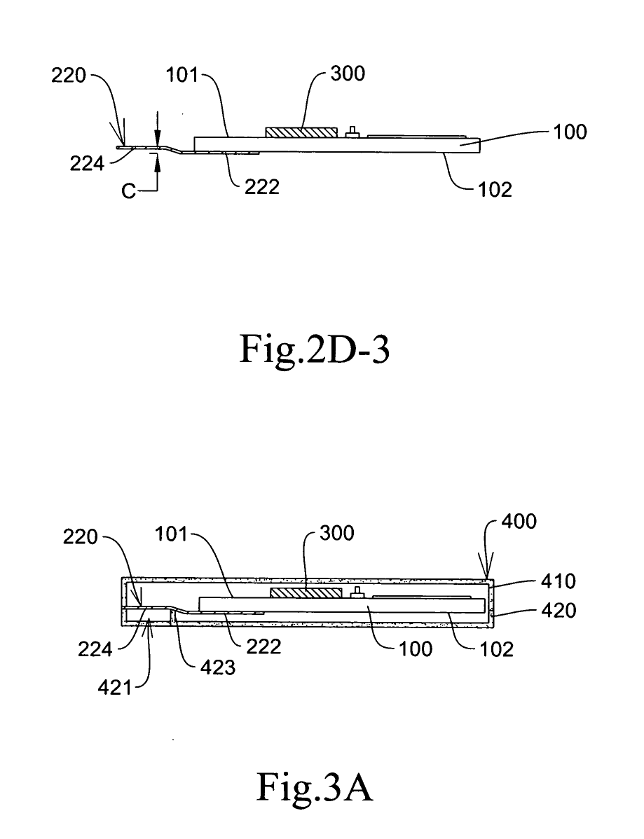

Firstly, please refer to FIG. 2A, FIG. 2B and FIG. 2C are top-view diagrams illustrating of a manufacturing method of a substrate of a secure digital input/output module interface according to one embodiment of the present invention. According to one embodiment of the present invention, the manufacturing method of the substrate of the secure digital input/output module interface includes following steps. Firstly, as shown in FIG. 2A, a substrate 100 is provided, and the substrate 100 has a plurality of conductive contact portions 110 abreast arranged on a lower surface 102 of the substrate 100. Next, please refer to FIG. 2B, a lead frame 200 is provided. The lead frame 200 has a side rail 210 and a plurality of fingers 220 abreast arranged on the side rail 210, wherein any one of those fingers 220 includes an internal contact 222 and an external contact 224. In one embodiment, the number of those fingers 220 on the lead frame 200 is depended on the designed application module of the SDIO interface so that those fingers 220 may be formed with different basic units. Furthermore, please refer to FIG. 2C, the internal contacts 222 of those fingers 220 are electrically connected to those conductive contact portions 110 of the substrate 100. In one embodiment, the electrically connecting method between those internal contacts 222 and those conductive contact portions 110 includes a welding method. In another embodiment, as shown in FIG. 2C, the substrate structure further includes an application module 300 set on an upper surface 101 of the substrate 100, and then the application module 300 is electrically connected to the substrate 100.

Continuously, the substrate structure of a secure digital input/output module interface includes the substrate 100 and the lead frame 200. The substrate 100 has a plurality of conductive contact portions 110 arranged abreast on the lower surface (not shown) of the substrate 100. Next, the lead frame 200 has a side rail 210 and a plurality of fingers 220 abreast arranged on the side rail 210. Such as shown in FIG. 2C, any one of those fingers 220 includes an internal contact 222 and an external contact 224. Besides, the internal contact 222 of any one of those fingers 220 is electrically contacted to any one of those conductive contact portions 110 on the substrate 100. Additionally, the external contact 224 of any one of those fingers 220 is jointed to the side rail 210. In one embodiment, those external contacts 224 of those fingers 220 are connected to the side rail 210 by using a plurality of connecting section 226. In one aspect, the application module 300 is set on the upper surface 101 of the substrate 100, wherein the application module 300 may be selected from a memory module, such as a Bluetooth module, a Wi-Fi module, a COMBO card and a FM/AM broadcasting card.

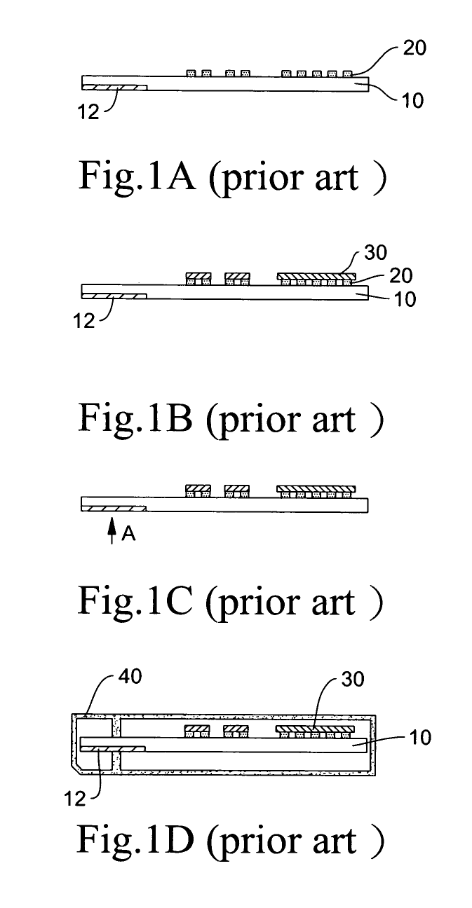

Accordingly, another embodiment of the substrate of the secure digital input/output module interface manufacturing method further comprises a sigulation process to form a plurality of the substrates of the SDIO module interface by sigulating in accordance with a unit of the substrate. As shown in FIG. 2D-1, FIG. 2D-1 is a bottom-view diagram illustrating the substrate structure of the secure digital input/output module interface, wherein the sigulation process may separate those fingers 220 from the side rail 210 by using the stamping method (Refer to FIG. 2C). After the sigulation process is accomplished, an individual substrate structure of the SDIO module interface is formed and the substrate structure includes the substrate 100 and those fingers 220.

Please refer to FIG. 2D-1 anew, those fingers 220 relatively positioned to the conductive contact portions 110 of the substrate 100, wherein any one of those fingers 220 includes the internal contact 222 and the external contact 224. And, those internal contacts 222 are electrically connected to any one of those conductive contact portions 110 of the substrate 100 to achieve electrical conduction. Further, after the sigulation process is accomplished, the external contact 224 of any one of those fingers 220 is formed to be a free end.

Please referring to the FIG. 2D-2 is a top-view diagram illustrating the substrate of the secure digital input/output module interface. As shown in FIG. 2D-2, the application module 300 may be set on the upper surface 101 of the substrate 100 and electrically connected with the substrate 100. In one embodiment, the application module 300 includes a memory module, a Bluetooth module, a Wi-Fi module, a COMBO card or a FM/AM broadcasting card and so on.

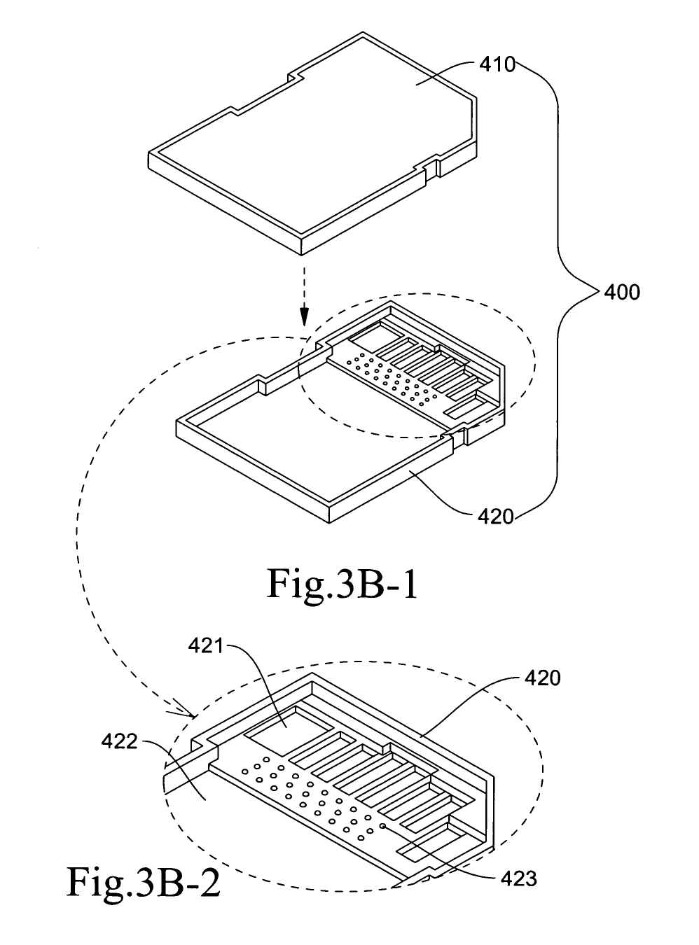

In order to describe the substrate structure specifically, please refer to FIG. 2D-3 that takes the cross-segment BB from FIG. 2D-2. As shown in FIG. 2D-3, those fingers 220 are set on the lower surface 102 of the substrate 100 by using welding method or other connecting methods, and furthermore those fingers 220 are electrically connected to the substrate 100. In the above embodiment, there is a height difference C between the internal contact 222 and the external contact 224 of any on of those fingers 220 or each finger 220. Due to the length of those fingers 220 may be designed according to the users request so that the conventional golden finger of the substrate can be replaced to reduce the utility area of the substrate as well as decrease the production cost.

Please refer to FIG. 3A that is another embodiment of the present invention. The manufacturing method of the SDIO module interface is applied on the abovementioned manufacturing method of substrate of the SDIO module interface, and the steps before sigulation process are the same as the abovementioned embodiment.

After sigulation process, a shell body 400 is formed to encapsulate the substrate 100 and part of those fingers 220, wherein those external contacts 224 of those fingers 220 expose to the shell body 400 so as to transmit information via an exterior reader (not shown). In an embodiment, the shell body 400 may be formed by using the injection molded method or ultrasonic bonding method. In another embodiment, in order to bear an insertion/withdrawal force, a metal layer may be formed on the SDIO module, such as coating an Au layer on those fingers 220, to enforce its mechanical properties. Accordingly, please refer to the FIG. 3B-1 and FIG. 3B-2, FIG. 3B-1 is a 3-dimensional diagram illustrating the shell body 400, and FIG. 3B-2 is a partially enlarged diagram illustrating FIG. 3B-1. As shown in these figures, the structure further includes a plurality of protruding portions 423 protruding from the interior 422 of the shell body 400. In the meanwhile, those protruding portions 423 may be formed to support or orientate those fingers 220 according to different location of the interior 422 where those protruding portions 423 set (shown in FIG. 3A). In addition, the shell body 400 has a plurality of openings 421 positioned relatively to those fingers 220 to expose those fingers 220(shown in FIG. 3A).

Thereafter, please refer to the FIG. 3A again illustrating SDIO module interface structure after the shell body 400 is formed, the SDIO module includes a substrate 100, a plurality of fingers 220 and a shell body 400, wherein the shell body 400 encapsulates the substrate 100 and the part of fingers 220. The difference aspect between the present embodiment and the abovementioned embodiment is the shell body formed by using an injection molded method or an ultrasonic bonding method to encapsulate the substrate structure for implementing the structure of the SDIO module interface.

In one embodiment, the shell body 400 may includes an upper shell body 410 and a lower shell body 420, and the lower shell body 420 has the openings 421 to expose the external contacts 224 of those fingers 220. In such a situation, the application 300 mounted on the substrate 100 may be electrically connected to the substrate 100 and those exposed external contacts 224 may communicate with an external reader (not shown). Please refer to FIG. 3A and FIG. 3B-1, the shell body 400 is formed with the upper shell body 410 and the lower shell body 420 by utilizing the ultrasonic bonding method in the direction of dotted arrow to encapsulate the substrate 100.

Accordingly, please refer to FIG. 3A, in one embodiment, there is a height difference between the internal contact 222 and the external contact 224 of each finger 220, wherein the height difference may be formed while the lead frame manufacturing process is performed or it may be formed while the substrate structure is separated by using the stamping process. In addition, the protruding portions 423 protrude from the interior of the lower shell body 420 to support those fingers 220 which includes the height difference. Moreover, in another embodiment, those protruding portions 423 may be set between each finger 220 with an inteval so as to orientate each finger 220. It is understood that the lower shell body 420 may have those protruding portions to support and orientate those fingers 220 both. Thereby, those protruding portions 423 may provide the supporting function as well as the fixing function simultaneously to raise production yields.

Accordingly, in another embodiment, in order to enhance the durability of the SDIO module, a metal layer (not shown), such as Au layer, may be coated on those fingers 220. Besides, the metal layer coated on those fingers 220 may strengthen the hardness of those fingers 220. Preferably, the usage effect of the metal layer which is coated on the lead frame is better than the usage effect of the coating formed on the conventional golden fingers of the substrate, and the manufacturing cost is much cheaper than the conventional golden fingers of the substrate.

Accordingly, those protruding portions protrude from the interior of the lower shell body may utilized to tightly touch and support those fingers provided with the height difference. Moreover, those protruding portions may be set between each finger with an i nterval so as to orientate each finger. It is appreciated that the lower shell body may have those protruding portions to support and orientate those fingers at the same time. Additionally, those protruding portions may be formed to support or orientate those fingers according to different location of the interior where those protruding portions set. Therefore, those protruding portions provide the supporting function as well as the fixing function simultaneously to elevate production yields.

To summarize, the present invention utilizes a lead frame provided with a plurality of external contacts of the SDIO module interface instead of the conventional golden fingers of the substrate. Hence, the mechanical properties, such as card insertion/withdraw enforce, can be elevated. In addition, the golden fingers of the conventional substrate may be replaced by the lead frame so as to reduce the substrate area and decrease the production cost.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A substrate structure of a secure digital input/output module interface comprising:
a substrate having a plurality of conductive contact portions abreast arranged on a lower surface of said substrate; and
a lead frame having a side rail and a plurality of fingers abreast arranged at said side rail, wherein
any one of those fingers comprises an internal contact and an external contact;
said internal contact of any one of those fingers electrically contactes to any one of those conductive contact portions of said substrate; and
said external contact of any one of those fingers is joined to said side rail.

2. The substrate structure of the secure digital input/output module interface according to claim 1, wherein said external contact of those fingers connectes to said side rail by using a plurality of connecting sections.

3. The substrate structure of the secure digital input/output module interface according to claim 1, further comprising an application module arranged on an upper surface of said substrate.

4. The substrate structure of the secure digital input/output module interface according to claim 3, wherein said application module comprises a memory module, a Bluetooth module, a Wi-Fi module, a COMBO card and a FM/AM broadcasting card.

5. A substrate structure of a secure digital input/output module interface comprising:
a substrate having a plurality of conductive contact portions abreast arranged on a lower surface of said substrate; and
a plurality of fingers positioned relatively to those conductive contact portions of said substrate, wherein
any one of those fingers comprises an internal contact and an external contact;
said internal contact of any one of those fingers electrically contacts with any one of those conductive contact portions of said substrate; and
said external contact of any one of those fingers is formed to be a free end.

6. The substrate structure of the secure digital input/output module interface according to claim 5, further comprising an application module arranged on an upper surface of said substrate.

7. The substrate structure of the secure digital input/output module interface according to claim 6, wherein said application module comprises a memory module, a Bluetooth module, a Wi-Fi module, a COMBO card and a FM/AM broadcasting card.

8. The substrate structure of the secure digital input/output module interface according to claim 5, wherein there is a height difference formed between said internal contact and said external contact.

9. A structure of a secure digital input/output module interface applied on the substrate structure of the secure digital input/output module interface according to claim 5, which comprising a shell body encapsulating said substrate and part of those fingers, wherein said external contact of any one of those fingers is exposed to said shell body.

10. The structure of the secure digital input/output module interface according to claim 9, wherein said shell body comprises an upper shell body and a lower shell body.

11. The structure of the secure digital input/output module interface according to claim 10, wherein said lower shell body has a plurality of protruding portions protruding from an interior of said lower shell body.

12. The structure of the secure digital input/output module interface according to claim 11, wherein those protruding portions are set between each said finger with an interval or tightly touch and support those fingers.

13. The structure of the secure digital input/output module interface according to claim 9, wherein there is a high difference between said internal contact and said external contact of each said finger.

14. A manufacturing method to a substrate of a secure digital input/output module interface, comprising:
providing a substrate with a plurality of conductive contact portions abreast arranged on a lower surface of said substrate;
providing a lead frame with a side rail and a plurality of fingers abreast set thereon, wherein any one of those fingers comprises an internal contact and an external contact; and
electrically connecting said internal contact of any one of those fingers to any one of those conductive contact portions of said substrate.

15. The manufacturing method to the substrate of the secure digital input/output module interface according to claim 14, wherein the electrically connecting method between those internal contacts and those conductive contact portions comprises a welding method.

16. The manufacturing method to the substrate of the secure digital input/output module interface according to claim 14, further comprising setting an application module on an upper surface of said substrate and electrically connected said application module to said substrate.

17. The manufacturing method to the substrate of the secure digital input/output module interface according to claim 14, further comprising a sigulation process to form a plurality of secure digital input/output module interfaces by sigulating in accordance with a unit of each said substrate.

18. A manufacturing method of a secure digital input/output module interface applied on the substrate of the secure digital input/output module interface according to claim 14, comprising the step of forming a shell body to encapsulate said substrate and part of those fingers, wherein said external contact of any one of those fingers is exposed to said shell body.

19. The manufacturing method of the secure digital input/output module interface according to claim 18, wherein said sigulation process is used to separate those fingers from said side rail by using a stamping method.

20. The manufacturing method of the secure digital input/output module interface according to claim 18, wherein said shell body is formed by using an injection molded method.

21. The manufacturing method of the secure digital input/output module interface according to claim 18, wherein said shell body is implemented by using an ultrasonic welding method.

22. The manufacturing method of the secure digital input/output module interface according to claim 18, further comprising forming a plurality of protruding portions protruding from an interior of said shell body to support those fingers.

23. The manufacturing method of the secure digital input/output module interface according to claim 18, further comprising forming a plurality of protruding portions protruding from an interior of said shell body to orientate those fingers.

24. The manufacturing method of the secure digital input/output module interface according to claim 18, further comprising a stamping process to make a height difference between said internal contact and said external contact of any one of those fingers.

25. The manufacturing method of the secure digital input/output module interface according to claim 18, further comprising forming a metal layer on those fingers.
